(19) United States
(12) Patent Application Publication
(10) Pub. No.: US 2026/0143800 A1
(43) Pub. Date: May 21, 2026

(54) SEMICONDUCTOR DEVICE

(71) Applicant: Sony Group Corporation, Tokyo (JP)

(72) Inventors: Tetsuya Ikuta, Kanagawa (JP); Hitoshi Wakabayashi, Tokyo (JP)

(21) Appl. No.: 18/706,541

(22) PCT Filed: Aug. 4, 2022
(86) PCT No.: PCT/JP2022/029894

§ 371 Date: May 1, 2024

(30) Foreign Application Priority Data
Nov. 12, 2021 (JP) 2021-184926

(51) Int. Cl. H10D 84/83; H10D 30/00; H10D 30/01; H10D 30/43; H10D 62/10; H10D 84/01

(52) U.S. Cl. CPC H10D 84/833; H10D 30/43; H10D 30/502; H10D 62/102; H10D 62/121; H10D 30/014; H10D 30/0191; H10D 84/0128

(57) ABSTRACT

Application of appropriate back bias to a channel of an FET having nanowires or nanosheets is disclosed. In one example, a semiconductor device includes a body electrode extending in a direction perpendicular to a main surface of a substrate; a channel layer extending from a side surface of the body electrode in a first direction parallel to the main surface via an insulating film; a source layer and a drain layer that are in contact with side surfaces of the channel layer in a second direction perpendicular to the first direction and sandwich the channel layer; and a gate electrode provided between the source layer and the drain layer and covering the channel layer with a gate insulating film interposed therebetween.

### TECHNICAL FIELD

The present disclosure relates to a semiconductor device.

### BACKGROUND ART

In recent years, miniaturization of MOS (Metal-Oxide-Semiconductor) transistors has progressed. For example, in MOSFETs (MOS Field-Effect Transistors) of the 14 nm generation and later, a three-dimensional Fin structure has been adopted in place of the planar structure of the up to 20 nm generation.

Furthermore, a structure using nanowires or nanosheets has been proposed as a structure that can be made even smaller than the three-dimensional Fin structure.

On the other hand, in MOSFETs, it is known that by applying a back bias to a region where a channel is formed, the operation and performance of the MOSFET can be improved and a leakage current can be reduced.

Therefore, even in MOSFETs using nanowires or nanosheets, it is being considered to apply a back bias to the nanowires or nanosheets in which channels are formed. For example, PTL 1 and PTL 2 listed below disclose a technique in which a back bias is applied from a substrate to nanowires provided on a substrate via a resistance or capacitance.

### Citation List

### Patent Literature

PTL 1

WO 2020/021913
PTL 2

WO 2019/150947

### SUMMARY

### Technical Problem

However, in the techniques disclosed in PTL 1 and PTL 2, since the supply of potential from the substrate to the nanowires is unstable, it is difficult to apply an appropriate back bias to the nanowires where channels are formed.

Therefore, the present disclosure proposes a new and improved semiconductor device that can apply an appropriate back bias to the channel of an FET having nanowires or nanosheets.

### Solution to Problem

According to the present disclosure, there is provided a semiconductor device including: a body electrode extending in a direction perpendicular to a main surface of a substrate; a channel layer extending from a side surface of the body electrode in a first direction parallel to the main surface via an insulating film; a source layer and a drain layer that are in contact with side surfaces of the channel layer in a second direction perpendicular to the first direction and sandwich the channel layer; and a gate electrode provided between the source layer and the drain layer and covering the channel layer with a gate insulating film interposed therebetween.

### BRIEF DESCRIPTION OF DRAWINGS

FIG. 1 is a plan view of a semiconductor device according to a first structure viewed from above.

FIG. 2 is a longitudinal cross-sectional view showing an example of the cross-sectional structure of the semiconductor device taken along line A-AA in FIG. 1.

FIG. 3 is a longitudinal cross-sectional view showing another example of the cross-sectional structure of the semiconductor device taken along the line A-AA in FIG. 1.

FIG. 4 is an explanatory diagram showing a planar configuration of a semiconductor device according to a second structure viewed from above, and a cross-sectional structure of the semiconductor device along a predetermined cutting line.

FIG. 5 is an explanatory diagram illustrating one step of the manufacturing process of the semiconductor device according to the second structure from a plan view and a cross-section.

FIG. 6 is an explanatory diagram illustrating one step of the manufacturing process of the semiconductor device according to the second structure from a plan view and a cross-section.

FIG. 7 is an explanatory diagram illustrating one step of the manufacturing process of the semiconductor device according to the second structure from a plan view and a cross-section.

FIG. 8 is an explanatory diagram illustrating one step of the manufacturing process of the semiconductor device according to the second structure from a plan view and a cross-section.

FIG. 9 is an explanatory diagram illustrating one step of the manufacturing process of the semiconductor device according to the second structure from a plan view and a cross-section.

FIG. 10 is an explanatory diagram illustrating one step of the manufacturing process of the semiconductor device according to the second structure from a plan view and a cross-section.

FIG. 11 is an explanatory diagram illustrating one step of the manufacturing process of the semiconductor device according to the second structure from a plan view and a cross-section.

FIG. 12 is an explanatory diagram illustrating one step of the manufacturing process of the semiconductor device according to the second structure from a plan view and a cross-section.

FIG. 13 is an explanatory diagram illustrating one step of the manufacturing process of the semiconductor device according to the second structure from a plan view and a cross-section.

FIG. 14 is an explanatory diagram illustrating one step of the manufacturing process of the semiconductor device according to the second structure from a plan view and a cross-section.

FIG. 15 is an explanatory diagram illustrating one step of the manufacturing process of the semiconductor device according to the second structure from a plan view and a cross-section.

FIG. 16 is an explanatory diagram illustrating one step of the manufacturing process of the semiconductor device according to the second structure from a plan view and a cross-section.

FIG. 17 is an explanatory diagram illustrating one step of the manufacturing process of the semiconductor device according to the second structure from a plan view and a cross-section.

FIG. 18 is an explanatory diagram illustrating one step of the manufacturing process of the semiconductor device according to the second structure from a plan view and a cross-section.

FIG. 19 is an explanatory diagram showing a planar configuration of a semiconductor device according to a first modification example viewed from above, and a cross-sectional structure of the semiconductor device along a predetermined cutting line.

FIG. 20 is an explanatory diagram showing a planar configuration of a semiconductor device according to a second modification example viewed from above, and a cross-sectional structure of the semiconductor device along a predetermined cutting line.

FIG. 21 is an explanatory diagram showing a planar configuration of a semiconductor device according to a third modification example viewed from above, and a cross-sectional structure of the semiconductor device along a predetermined cutting line.

FIG. 22 is an explanatory diagram showing a planar configuration of a semiconductor device according to a fourth modification example viewed from above, and a cross-sectional structure of the semiconductor device along a predetermined cutting line.

### DESCRIPTION OF EMBODIMENTS

Preferred embodiments of the present disclosure will be described in detail with reference to the accompanying figures below. Further, in the present specification and the figures, components having substantially the same functional configuration will be denoted by the same reference numerals, and thus repeated descriptions thereof will be omitted.

Further, the description will be given in the following order.
1. Structure
1.1. First structure
1.2. Second structure
2. Manufacturing method
3. Modification example
3.1. First modification example
3.2. Second modification example
3.3. Third modification example
3.4. Fourth modification example

### 1. Structure

### 1.1. First Structure

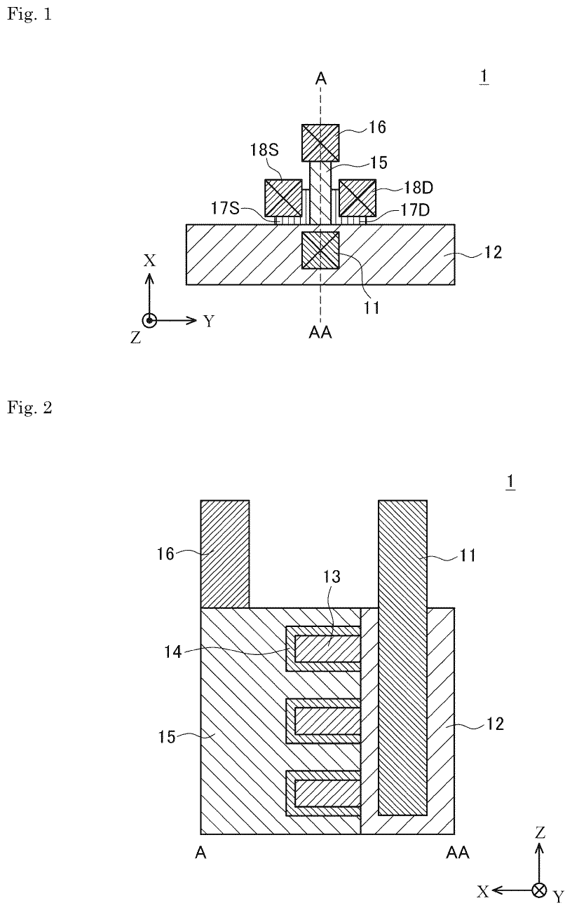

First, with reference to FIGS. 1 and 2, a first structure of a semiconductor device according to an embodiment of the present disclosure will be described. FIG. 1 is a plan view of a semiconductor device 1 according to a first structure viewed from above. FIG. 2 is a longitudinal cross-sectional view showing an example of the cross-sectional structure of the semiconductor device 1 taken along line A-AA in FIG. 1.

As shown in FIGS. 1 and 2, the semiconductor device 1 according to the first structure includes, for example, a body electrode 11, a body insulating layer 12, a channel layer 13, a gate insulating film 14, a gate electrode 15, a gate contact 16, a source layer 17S, a drain layer 17D, a source electrode 18S, and a drain electrode 18D. The semiconductor device 1 is, for example, a MOSFET that allows current to flow between the source layer 17S and the drain layer 17D via a channel formed in the channel layer 13.

Note that in the following, a first conductivity type impurity and a second conductivity type impurity refer to impurities having different conductivity types. For example, when the first conductivity type impurity is a p-type impurity (for example, B or Al), the second conductivity type impurity is an n-type impurity (for example, P or As). Furthermore, when the first conductivity type impurity is an n-type impurity (for example, P or As), the second conductivity-type impurity is a p-type impurity (for example, B or Al).

The semiconductor device 1 is provided on, for example, a Si substrate or an SOI (Silicon On Insulator) substrate (not shown). In FIGS. 1 and 2, the direction perpendicular to the main surface of the substrate on which the semiconductor device 1 is provided is defined as the Z direction, one direction within the plane of the main surface of the substrate is defined as the X direction, and the direction orthogonal to the X direction within the plane of the main surface of the substrate is defined as the Y direction.

The body electrode 11 is provided extending in a direction (that is, the Z direction) perpendicular to the main surface of the substrate on which the semiconductor device 1 is provided. Specifically, the body electrode 11 may be provided extending in the Z direction inside of an opening formed in the body insulating layer 12 to face the channel layer 13. The body electrode 11 is capacitively coupled to the channel layer 13 via the body insulating layer 12 on the side surface of the body electrode 11. Thus, a body potential that is a back bias can be supplied to the channel layer 13. The body electrode 11 may be made of a conductive material containing a single substance or a compound of Si, poly-Si, Al, Cu, Au, W, Ta, Ti, Mo, or Ru, for example. In particular, body contact characteristics can be stabilized by forming the body electrode 11 from a metal material such as Mo or Ru that has a small diffusion coefficient in SiOₓ.

The body insulating layer 12 has the body electrode 11 therein, and is provided extending in the Y direction on the substrate, for example. The body insulating layer 12 can capacitively couple the channel layer 13 and the body electrode 11 provided inside of the body insulating layer 12 to face the channel layer 13. The body insulating layer 12 can appropriately capacitively couple the channel layer 13 and the body electrode 11 because the thickness between the body electrode 11 and the channel layer 13 can be controlled by the position of the opening where the body electrode 11 is provided. The body insulating layer 12 may be made of an insulating material such as SiOₓ, SiN, SiON, HfOₓ, ZrOₓ, Al₂O₃, or NbOₓ. In particular, body contact characteristics can be improved by forming the body insulating layer 12 from an insulating material with a high relative dielectric constant such as HfOₓ, ZrOₓ, Al₂O₃, or NbOₓ.

The channel layer 13 is provided extending from the side surface of the body electrode 11 via the body insulating layer 12 in a first direction (for example, the X direction) parallel to the main surface of the substrate. For example, a plurality of channel layers 13 may be provided in a comb-like shape parallel to the main surface of the substrate from the side surface of the body insulating layer 12 facing the body electrode 11. The channel layer 13 is configured, for example, as nanowires or nanosheets of a semiconductor material such as Si, SiGe, Ge, or InGaAs into which a first conductivity type impurity is introduced. The nanowires or nanosheets are, for example, a structure having a diameter or film thickness of 10 nm or less, preferably 2 nm or more and 10 nm or less. By providing the nanowires or nanosheets with a diameter or film thickness of 2 nm or more, high mobility of electrons or holes can be maintained. Moreover, the short channel characteristics of the MOSFET can be improved by providing the nanowires or nanosheets into a diameter or film thickness of 10 nm or less. In MOSFETs, nanowires or nanosheets can function as channels surrounded by gates on multiple sides, thereby suppressing short channel effects and increasing the effective channel width.

The source layer 17S and the drain layer 17D are provided in contact with both side surfaces of the channel layer 13 in a second direction (for example, the Y direction) orthogonal to the first direction (for example, the X direction), and sandwich the channel layer 13 therebetween. In this way, the channel layer 13 can function as a channel that allows current to pass between the source layer 17S and the drain layer 17D. The amount of current flowing between the source layer 17S and the drain layer 17D is controlled by the conductance of the channel layer 13. The conductance of the channel layer 13 can be controlled by, for example, a voltage applied to the gate electrode 15. The source layer 17S and the drain layer 17D may be made of a semiconductor material such as Si, SiGe, or Ge that is epitaxially grown by introducing a second conductivity-type impurity, for example.

Further, when a plurality of channel layers 13 are provided in a comb-like shape from the side surface of the body insulating layer 12 in parallel to the main surface of the substrate, the source layer 17S and the drain layer 17D may be provided to sandwich both side surfaces in the Y direction of each of the plurality of channel layers 13. Specifically, the source layer 17S and the drain layer 17D are provided extending in a direction (for example, the Z direction) perpendicular to the main surface of the substrate, thereby sandwiching both side surfaces of each of the plurality of channel layers 13.

The source electrode 18S is provided on the source layer 17S, and functions as a source terminal of the MOSFET by being electrically connected to the source layer 17S. The drain electrode 18D is provided on the drain layer 17D, and functions as a drain terminal of the MOSFET by being electrically connected to the drain layer 17D. The source electrode 18S and the drain electrode 18D may be made of a single substance or a compound of Si, poly-Si, Al, Cu, Au, W, Ta, Ti, Mo, or Ru, which has conductivity, for example. In particular, contact characteristics can be stabilized by forming the source electrode 18S and the drain electrode 18D from a metal material such as Mo or Ru that has a small diffusion coefficient in SiOₓ.

The gate electrode 15 is provided between the source layer 17S and the drain layer 17D, and is provided to three-dimensionally cover the channel layer 13. Specifically, the gate electrode 15 is provided in the space between the source layer 17S, the drain layer 17D, and the body insulating layer 12 to fill the space around the channel layer 13. According to this configuration, the gate electrode 15 can cover the upper surface and lower surface of the channel layer 13 in the Z direction, as well as the side surface on the tip side in the X direction. Thus, a channel can be formed on three surfaces of the channel layer 13 through the gate insulating film 14: the upper surface, the lower surface, and the side surface on the tip side in the X direction. The gate electrode 15 may be made of, for example, a single substance or a compound (for example, oxides or nitrides) of Ti, W, Ta, Al, Ru, Mo, La, or Mg, which has conductivity. In particular, the controllability of the threshold voltage by work function or dipole control can be improved by forming the gate electrode 15 from a single substance or a compound of Ru, Mo, La, or Mg.

The gate insulating film 14 is provided between the channel layer 13 and the gate electrode 15. Specifically, the gate insulating film 14 is provided along three surfaces of the channel layer 13: the upper surface and lower surface in the Z direction, and the side surface on the tip side in the X direction. The gate insulating film 14 may be made of, for example, SiOₓ, SiN, or SiON. Further, the gate insulating film 14 may be made of a high dielectric constant material (high-k material) such as HfOₓ, HfAlON, Y₂O₃, ZrOₓ, Al₂O₃, or NbOₓ, or may be made of oxides or nitrides of Ru, Mo, La, or Mg. According to this configuration, the transistor characteristics can be improved and the controllability of the threshold voltage by work function or dipole control can be improved by forming the gate insulating film 14 from an insulating material with a high relative dielectric constant.

The gate contact 16 is provided on the gate electrode 15 and functions as a gate terminal of the MOSFET by being electrically connected to the gate electrode 15. The gate contact 16 may be made of, for example, a single substance or a compound of Si, poly-Si, Al, Cu, Au, W, Ta, Ti, Mo, or Ru, which has conductivity. The contact characteristics can be stabilized by forming the gate contact 16 from a metal material such as Mo or Ru that has a small diffusion coefficient in SiOₓ.

According to the above-described configuration, the semiconductor device 1 can more easily supply a body potential to the channel layer 13 by the body electrode 11 extending in a direction perpendicular to the main surface of the substrate.

Further, in the semiconductor device 1, the thickness of the body insulating layer 12 between the body electrode 11 and the channel layer 13 can be easily controlled by the position of the opening in which the body electrode 11 is provided. According to this configuration, the semiconductor device 1 can appropriately control the capacitive coupling between the body electrode 11 and the channel layer 13. Thus, an appropriate body potential can be supplied to the channel layer 13 as a back bias. Therefore, the semiconductor device 1 can improve the operation and performance as a MOSFEET.

### Modification Example

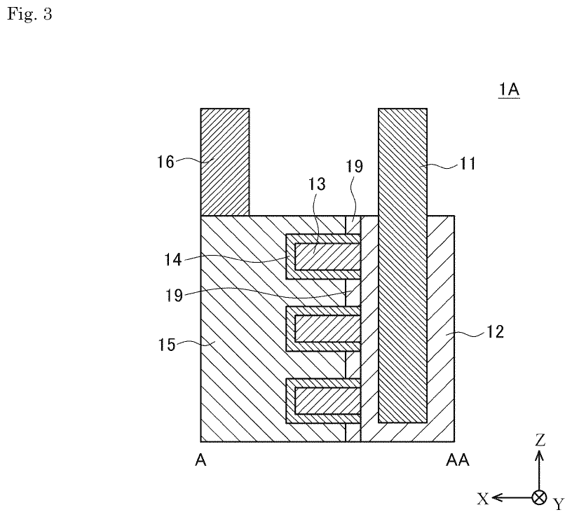

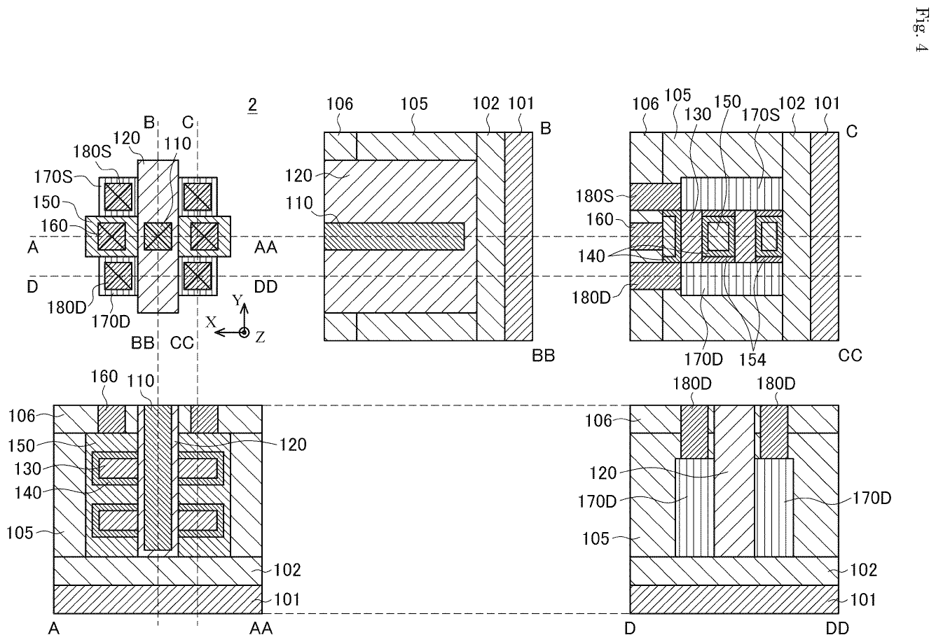

Furthermore, with reference to FIGS. 1 and 3, a modification example of the semiconductor device 1 according to the first structure will be described. FIG. 3 is a longitudinal cross-sectional view showing another example of the cross-sectional structure of the semiconductor device 1 taken along line A-AA in FIG. 1.

As shown in FIGS. 1 and 3, in a modification example of the semiconductor device 1, a capacitance control layer 19 is further provided between the body insulating layer 12 and the gate electrode 15. The capacitance control layer 19 is provided on a side surface of the body insulating layer 12 on which the channel layer 13 and the gate insulating film 14 are not provided.

For example, the capacitance control layer 19 may be provided by selectively and partially oxidizing a region of the gate electrode 15 made of poly-Si that is in contact with the body insulating layer 12 to form a SiOₓ layer. More specifically, first, a laminate in which the channel layer 13, the gate insulating film 14, and the gate electrode 15 are stacked is formed, and then an opening for forming the body insulating layer 12 and the body electrode 11 is provided to penetrate the laminate in the Z direction. The capacitance control layer 19 is provided by selectively and partially oxidizing the gate electrode 15 (poly-Si) exposed through the opening to form a SiOₓ layer.

Since the capacitance control layer 19 is made of an insulating material, the capacitance between the body electrode 11 and the gate electrode 15 can be controlled. For example, the capacitance control layer 19 can reduce the capacitance generated between the body electrode 11 and the gate electrode 15 by increasing the distance between the body electrode 11 and the gate electrode 15.

According to this configuration, in the modification example of the semiconductor device 1, since the capacitance between the body electrode 11 and the gate electrode 15 can be further reduced, the strength of the capacitive coupling between the body electrode 11 and the channel layer 13 can be relatively increased. Therefore, the modification example of the semiconductor device 1 can improve the controllability of the potential of the channel layer 13 by the body electrode 11.

### 1.2. Second Structure)

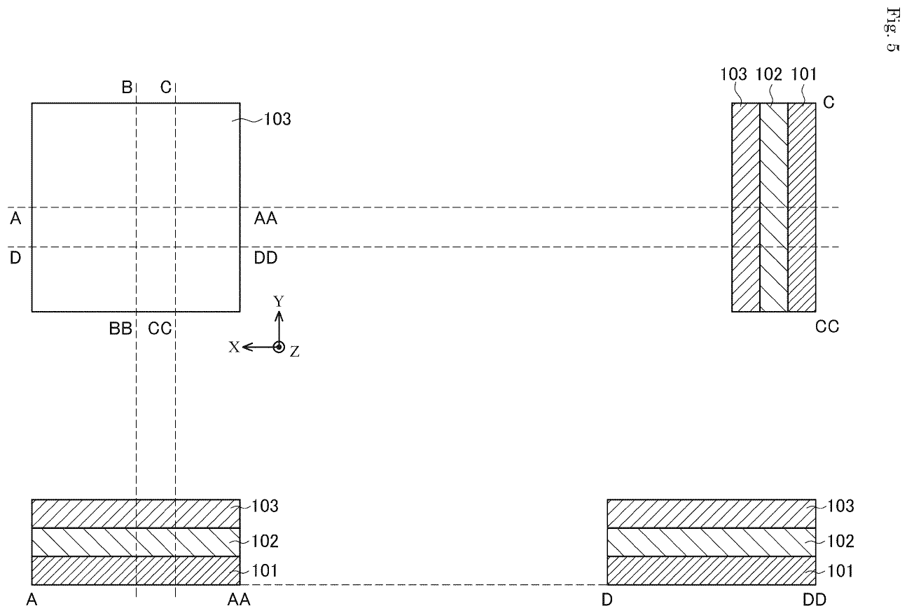

Next, with reference to FIG. 4, a second structure of the semiconductor device according to the present embodiment will be described. FIG. 4 is an explanatory diagram showing a planar configuration of the semiconductor device 2 according to the second structure viewed from above, and a cross-sectional structure of the semiconductor device 2 along a predetermined cutting line.

As shown in FIG. 4, the semiconductor device 2 according to the second structure includes a semiconductor layer 101, a substrate insulating layer 102, a body electrode 110, a body insulating layer 120, a channel layer 130, a gate insulating film 140, a gate electrode 150, a spacer layer 154, a gate contact 160, a source layer 170S, a drain layer 170D, a source electrode 180S, a drain electrode 180D, and interlayer insulation layers 105 and 106.

In the semiconductor device 2 according to the second structure, the channel layers 130 extend on both sides with the body insulating layer 120 extending in one direction as an axis of symmetry, and MOSFETs are formed on both sides with the body insulating layer 120 as the axis of symmetry. That is, the semiconductor device 2 according to the second structure is provided in a line-symmetrical structure with the body insulating layer 120 as the axis of symmetry. However, the semiconductor device 2 according to the second structure may have an asymmetric structure in which the MOSFET is provided only on one side.

The semiconductor layer 101 and the substrate insulating layer 102 constitute a substrate that supports the semiconductor device 2. For example, the semiconductor layer 101 is made of a semiconductor material such as Si. Further, the substrate insulating layer 102 may be made of an insulating material such as SiOₓ, may be made of an insulating material such as HfOₓ, ZrOₓ, Al₂O₃, or NbOₓ, and may be made of oxides or nitrides of Ru, Mo, La, or Mg. When the substrate insulating layer 102 is made of an insulating material such as HfOₓ, ZrOₓ, Al₂O₃, or NbOₓ, or oxides or nitrides of Ru, Mo, La, or Mg, the semiconductor device 2 can improve transistor characteristics by reducing the parasitic capacitance due to the substrate insulating layer 102. Furthermore, the semiconductor device 2 can also suppress variations in threshold voltage of MOSFETs by controlling fixed charges or dipoles.

For example, the semiconductor layer 101 and the substrate insulating layer 102 may be part of an SOI substrate in which an oxide layer (substrate insulating layer 102) such as SiOₓ is embedded inside of a semiconductor substrate (semiconductor layer 101) made of a semiconductor material such as Si. Alternatively, the semiconductor layer 101 and the substrate insulating layer 102 may be a Si substrate (semiconductor layer 101) on which an oxide layer (substrate insulating layer 102) is formed. The following description will be given assuming that the semiconductor layer 101 and the substrate insulating layer 102 are part of an SOI substrate.

However, the semiconductor device 2 may be supported by a Si substrate that does not have the substrate insulating layer 102. That is, the semiconductor device 1 may include only the semiconductor layer 101 instead of the semiconductor layer 101 and the substrate insulating layer 102. When the semiconductor device 2 is supported by a Si substrate without the substrate insulating layer 102, the manufacturing cost of the semiconductor device 2 can be reduced.

The body electrode 110 is provided on the substrate insulating layer 102 to extend in a direction (the Z direction in FIG. 4) perpendicular to the main surfaces of the semiconductor layer 101 and the substrate insulating layer 102. Specifically, the body electrode 110 may be provided extending in the Z direction inside of the body insulating layer 120 that is provided extending in one direction (that is, the Y direction) within the plane of the semiconductor layer 101 and the substrate insulating layer 102. The body electrode 110 may be made of a conductive material containing a single substance or a compound of Si, poly-Si, Al, Cu, Au, W, Ta, Ti, Mo, or Ru, for example. In particular, the body contact characteristics can be stabilized by forming the body electrode 110 from a metal material such as Mo or Ru that has a small diffusion coefficient in SiOₓ.

The body insulating layer 120 is provided extending in the Y direction within the plane of the semiconductor layer 101 and the substrate insulating layer 102, and divides the channel layer 130 extending in the X direction orthogonal to the Y direction. As a result, the channel layers 130 are provided on both sides of the body insulating layer 120 in the X direction, whereby MOSFETs are configured on both sides of the body insulating layer 120 in the X direction. The channel layers 130 provided on both sides of the body insulating layer 120 in the X direction are each supplied with a body potential, which is a back bias, through capacitive coupling from the body electrode 110 embedded inside of the body insulating layer 120. According to this configuration, the semiconductor device 2 can supply a body potential to a plurality of channel layers 130 with one terminal of the body electrode 110. The body insulating layer 120 may be made of an insulating material such as, for example, SiOₓ, SiN, SiON, HfOₓ, ZrOₓ, Al₂O₃, or NbOₓ. In particular, the body contact characteristics can be improved by forming the body insulating layer 120 from an insulating material with a high relative dielectric constant such as HfOₓ, ZrOₓ, Al₂O₃, or NbOₓ.

The channel layer 130 is provided extending from the side surface of the body electrode 110 in the X direction via the body insulating layer 120. Specifically, a plurality of channel layers 130 may be provided extending from the body insulating layer 120 in a comb-like shape parallel to the main surfaces of the semiconductor layer 101 and the substrate insulating layer 102 to face both side surfaces of the body electrode 110 in the X direction. According to this configuration, in the semiconductor device 2, MOSFETs can be provided line-symmetrically on both sides of the body insulating layer 120 in the X direction by providing the channel layer 130 line-symmetrically with the body insulating layer 120 as the axis of symmetry. The plurality of channel layers 130 extending in a comb-like shape are mutually supported in the Z direction by, for example, the spacer layers 154 provided along the side surfaces of the source layer 170S and the drain layer 170D.

The channel layer 130 may be formed of a semiconductor material such as Si, SiGe, Ge, or InGaAs into which a first conductivity type impurity is introduced, as nanowires or nanosheets with a diameter or film thickness of approximately 5 nm to 10 nm. Note that the channel layers 130 provided on both sides of the body electrode 110 in the X direction may be provided as semiconductor layers of the same first conductivity type because the same body potential is supplied from the body electrode 110.

The source layer 170S and the drain layer 170D are provided in contact with both side surfaces of the channel layer 130 in the Y direction, and sandwich the channel layer 130 in the Y direction. Specifically, the source layer 170S and the drain layer 170D are formed on the substrate insulating layer 102 to extend in the Z direction and be in contact with both side surfaces of each of the plurality of channel layers 130 that are provided in a comb-like shape and spaced apart from each other in the Z direction. The source layer 170S and the drain layer 170D may be made of a semiconductor material such as Si, SiGe, or Ge that is epitaxially grown by introducing a second conductivity type impurity, for example.

The source layer 170S and the drain layer 170D sandwich both side surfaces of the channel layer 130 in the Y direction. Thus, current can flow through the channel formed in the channel layer 130. Since the conductance of the channel layer 130 is controlled by, for example, the voltage applied to the gate electrode 150, the semiconductor device 2 can control the current flowing between the source layer 170S and the drain layer 170D by the voltage applied to the gate electrode 150.

The source electrode 180S is provided on the source layer 170S, and functions as a source terminal of the MOSFET by being electrically connected to the source layer 170S. The drain electrode 180D is provided on the drain layer 170D, and functions as a drain terminal of the MOSFET by being electrically connected to the drain layer 170D. The source electrode 180S and the drain electrode 180D may be made of, for example, a single substance or a compound of Si, poly-Si, Al, Cu, Au, W, Ta, Ti, Mo, or Ru, which has conductivity. In particular, the contact characteristics can be stabilized by forming the source electrode 180S and the drain electrode 180D from a metal material such as Mo or Ru that has a small diffusion coefficient in SiOₓ.

The spacer layer 154 is provided between the plurality of channel layers 130 provided apart from each other in the Z direction, and supports each of the plurality of channel layers 130 in the Z direction. Specifically, the spacer layer 154 may be provided along the side surfaces of the source layer 170S and the drain layer 170D between the plurality of channel layers 130 that have a comb-like shape in the Z direction. The spacer layer 154 is provided to insulate the source layer 170S and drain layer 170D from the gate electrode 150 with low capacitance. Further, the spacer layer 154 can support the plurality of channel layers 130 with respect to each other in the Z direction, and can prevent the source layer 170S and the drain layer 170D from being etched when forming the nanowire or nanosheet structure of the channel layer 130.

For example, the spacer layer 154 may be made of an insulating material containing Si, O, C, N, or B as an element, such as SiOₓ, SiN, or SiON. The parasitic capacitance can be further reduced by forming the spacer layer 154 from an insulating material with a lower relative dielectric constant. As another example, the spacer layer 154 may be made of an insulating material such as HfOₓ, ZrOₓ, Al₂O₃, or NbOₓ, or may be made of oxides or nitrides of Ru, Mo, La, or Mg. According to this configuration, since the spacer layer 154 can improve the etching resistance of a film, it is possible to control the structure of the semiconductor device 2 more precisely.

The gate electrode 150 is provided between the source layer 170S and the drain layer 170D, and is provided to three-dimensionally cover the channel layer 130 with the gate insulating film 140 interposed therebetween. Specifically, the gate electrode 150 is filled in the spaces between the plurality of channel layers 130 provided in a comb-like shape. Thus, the gate electrode 150 is provided to cover the upper and lower surfaces of the channel layer 130 in the Z direction via the gate insulating film 140 and the side surface on the tip side in the X direction. According to this configuration, the gate electrode 150 can form a channel on three surfaces of the channel layer 130, the upper surface and lower surface in the Z direction, and the side surface on the tip side in the X direction. Thus, the short channel effect can be suppressed and the effective channel width can be widened. The gate electrode 150 may be made of, for example, a single substance or a compound (for example, oxides or nitrides) of Ti, W, Ta, Al, Ru, Mo, La, or Mg, which has conductivity. In particular, the controllability of the threshold voltage by work function or dipole control can be improved by forming the gate electrode 150 from a single substance or a compound of Ru, Mo, La, or Mg.

The gate insulating film 140 is provided between the channel layer 130 and the gate electrode 150. Specifically, the gate insulating film 140 may be provided to cover the surfaces of the channel layer 130, the spacer layer 154, and the substrate insulating layer 102. For example, the gate insulating film 140 may be provided to cover the three surfaces of the channel layer 130, the upper and lower surfaces in the Z direction and the side surface on the tip side in the X direction, and the side surface of the spacer layer 154. The gate insulating film 140 may be made of, for example, SiOₓ, SiN, or SiON. Further, the gate insulating film 140 may be made of a high dielectric constant material (high-k material) such as HfOₓ, HfAlON, Y₂O₃, ZrOₓ, Al₂O₃, or NbOₓ, or may be made of oxides or nitrides of Ru, Mo, La, or Mg. According to this configuration, the transistor characteristics can be improved and the controllability of the threshold voltage by work function or dipole control can be improved by forming the gate insulating film 140 from an insulating material with a high relative dielectric constant.

The gate contact 160 is provided on the gate electrode 150 and functions as a gate terminal of the MOSFET by being electrically connected to the gate electrode 150. The gate contact 160 may be made of, for example, a single substance or a compound of Si, poly-Si, Al, Cu, Au, W, Ta, Ti, Mo, or Ru, which has conductivity. The contact characteristics can be stabilized by forming the gate contact 160 from a metal material such as Mo or Ru that has a small diffusion coefficient in SiOₓ.

The interlayer insulating layers 105 and 106 are made of an insulating material and electrically isolate the semiconductor device 2 from other circuits or elements by embedding the semiconductor device 2 therein. The interlayer insulating layers 105 and 106 may be made of an insulating material such as SiOₓ, SiN, or SiON, for example. Further, the interlayer insulating layers 105 and 106 may be made of an insulating material such as SiC, HfOₓ, ZrOₓ, Al₂O₃, or NbOₓ, or may be made of an air gap. The materials constituting the interlayer insulating layers 105 and 106 may be selected in consideration of ease of forming a wiring structure or reduction of delay due to wiring, in addition to insulation properties.

According to the above-described configuration, the semiconductor device 2 can more easily supply a body potential to the channel layer 130 by the body electrode 110 extending in a direction perpendicular to the main surface of the substrate including the semiconductor layer 101 and the substrate insulating layer 102.

Further, in the semiconductor device 2, the thickness of the body insulating layer 120 between the body electrode 110 and the channel layer 130 can be controlled with high precision by the position of the opening in which the body electrode 110 is provided. Therefore, since the semiconductor device 2 can appropriately control the capacitive coupling between the body electrode 110 and the channel layer 130, it is possible to supply an appropriate body potential to the channel layer 130.

Further, in the semiconductor device 2, the channel layer 130, the source layer 170S, and the drain layer 170D are provided on both sides of the body insulating layer 120 in the X direction in line symmetry with the body insulating layer 120 as the axis of symmetry. That is, in the semiconductor device 2, MOSFETs are formed on both sides of the body insulating layer 120 in the X direction. In such a case, the body electrode 110 can simultaneously supply the same body potential to the channel layers 130 provided on both sides of the body electrode 110 in the X direction. According to this configuration, the semiconductor device 2 can simultaneously supply the body potential to the plurality of channel layers 130 with one terminal, and therefore can supply the body potential to the plurality of MOSFETs with a simpler structure.

### 2. Manufacturing Method

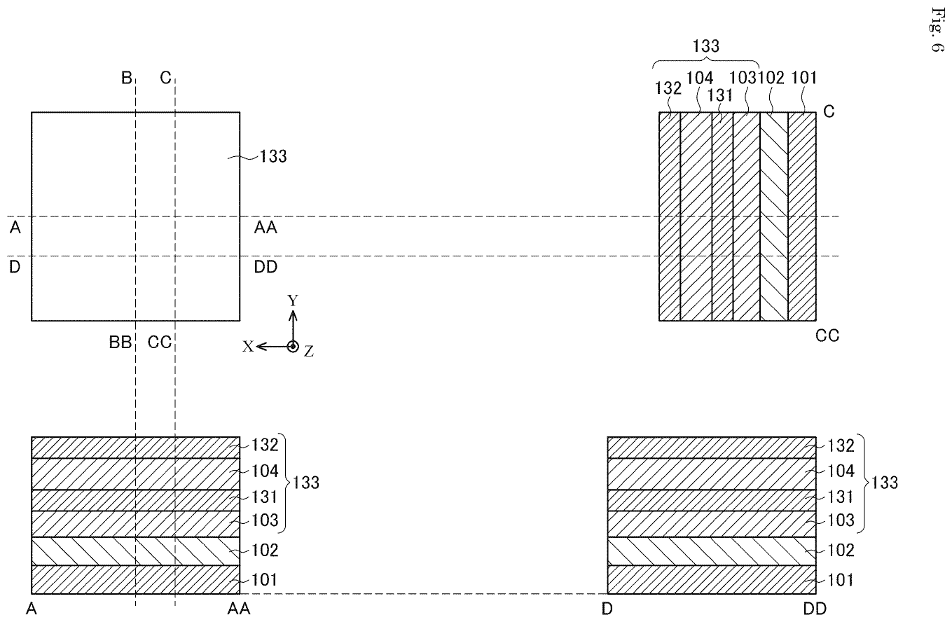

Next, a method for manufacturing the semiconductor device 2 according to the second structure will be described with reference to FIGS. 5 to 18. FIGS. 5 to 18 are explanatory diagrams illustrating each step of the manufacturing process of the semiconductor device 2 according to the second structure from a plan view and a cross-section.

First, as shown in FIG. 5, a substrate is prepared in which a first SiGe layer 103 is provided on a semiconductor layer 101 with a substrate insulating layer 102 interposed therebetween. The semiconductor layer 101 is, for example, a Si substrate, and the substrate insulating layer 102 is an oxide layer made of SiOₓ. As an example, the first SiGe layer 103 can be formed by bonding a structure in which a SiOₓ layer is formed on a Si substrate and a structure in which a SiOₓ layer is formed on a SiGe substrate with the SiOₓ layers facing each other and then thinning the SiGe substrate. As another example, the first SiGe layer 103 may be formed by a concentrated oxidation method in which SiGe is epitaxially grown on the Si layer of the SOI substrate and then thermally oxidized so that Ge moves toward the substrate. Thermal oxidation converts the Si layer of the SOI substrate into a SiGe layer, and the SiGe layer into an SiOₓ layer. Thus, by removing the SiOₓ layer, a structure in which the substrate insulating layer 102 and the first SiGe layer 103 are stacked on the semiconductor layer 101 can be formed.

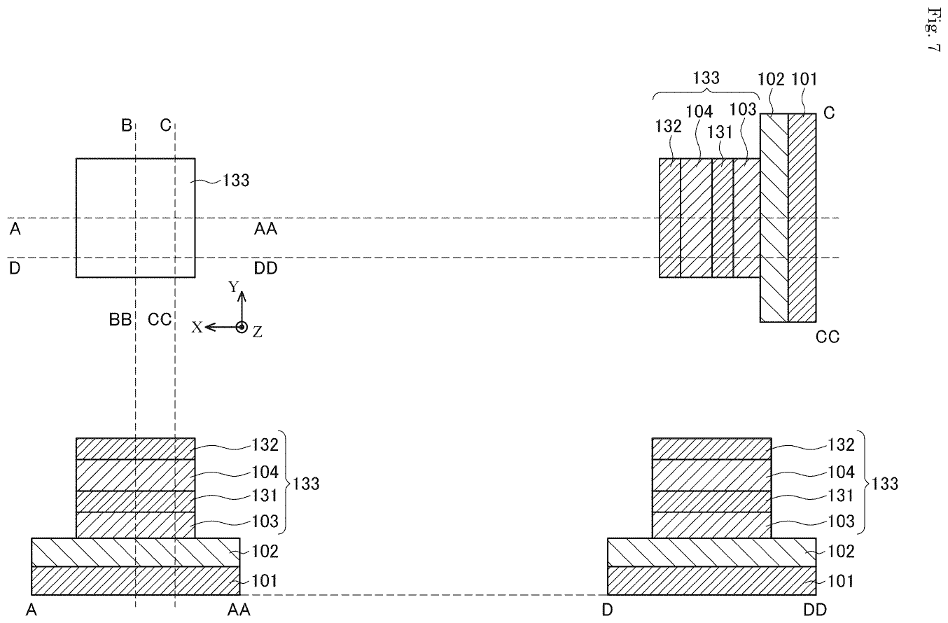

Next, as shown in FIG. 6, a first Si layer 131, a second SiGe layer 104, and a second Si layer 132 are sequentially formed on the first SiGe layer 103. The first Si layer 131 is formed by causing Si to be epitaxially grown on the first SiGe layer 103. The second SiGe layer 104 is formed by causing SiGe to be epitaxially grown on the first Si layer 131. The second Si layer 132 is formed by causing Si to be epitaxially grown on the second SiGe layer 104.

Hereinafter, the first SiGe layer 103, the first Si layer 131, the second SiGe layer 104, and the second Si layer 132 are also collectively referred to as an epitaxial layer 133. The epitaxial layer 133 is a layer in which a layer made of SiGe and a layer made of Si are alternately and repeatedly stacked.

However, in the epitaxial layer 133, the stacking order of the layer made of SiGe and the layer made of Si may be reversed. For example, the epitaxial layer 133 is formed by causing the first Si layer 131, the first SiGe layer 103, the second Si layer 132, and the second SiGe layer 104 to be sequentially epitaxially grown on the substrate insulating layer 102.

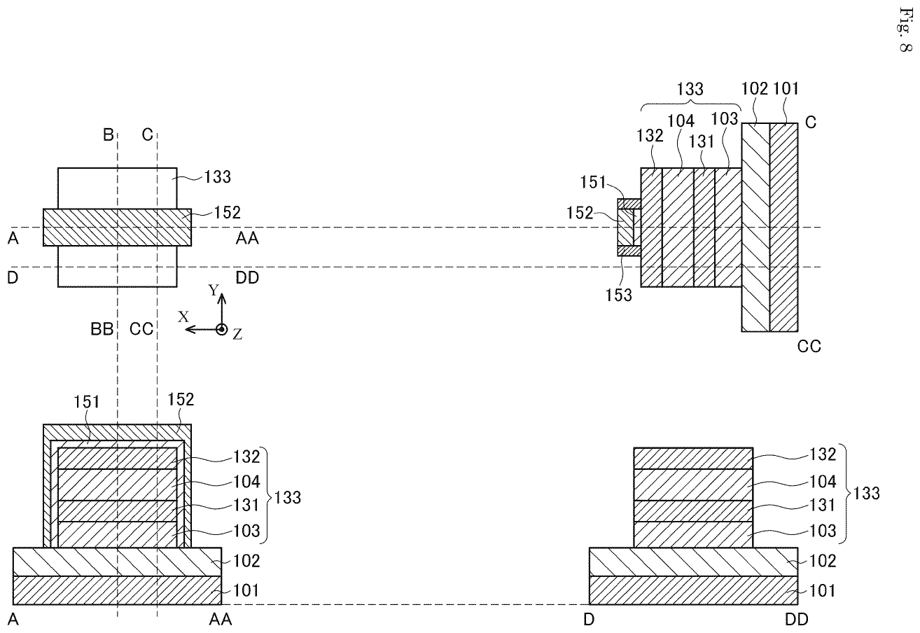

Subsequently, as shown in FIG. 7, the epitaxial layer 133 is patterned by lithography and etching. For example, the epitaxial layer 133 may be patterned by an STI (Shallow Trench Isolation) process. In the STI process, the epitaxial layer 133 is patterned, and an element isolation region (not shown) is formed in which an insulating material such as SiOₓ is deposited on the substrate insulating layer 102. The element isolation region is provided to electrically isolate the semiconductor device 2 from other circuits or elements.

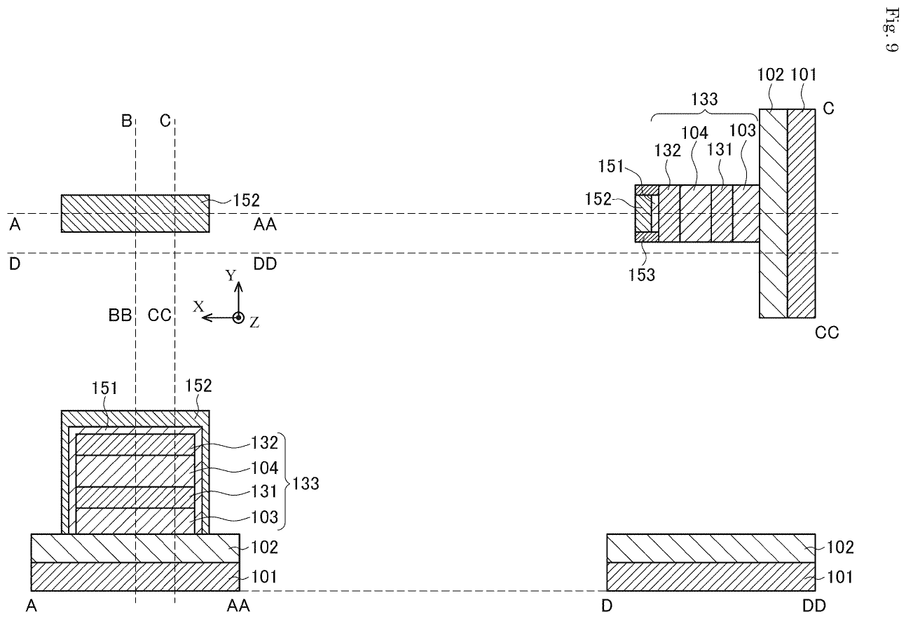

Next, as shown in FIG. 8, a dummy insulating film 151 and a dummy gate 152 are formed to cover the patterned epitaxial layer 133 in the X direction. Furthermore, dummy sidewalls 153 are formed on the side surfaces of the dummy gate 152 and the dummy insulating film 151. The dummy gate 152 is made of poly-SiGe, for example, because it is removed simultaneously with the first SiGe layer 103 and the second SiGe layer 104 in a later step. The dummy insulating film 151 and the dummy sidewall 153 are made of SiOₓ or SiN.

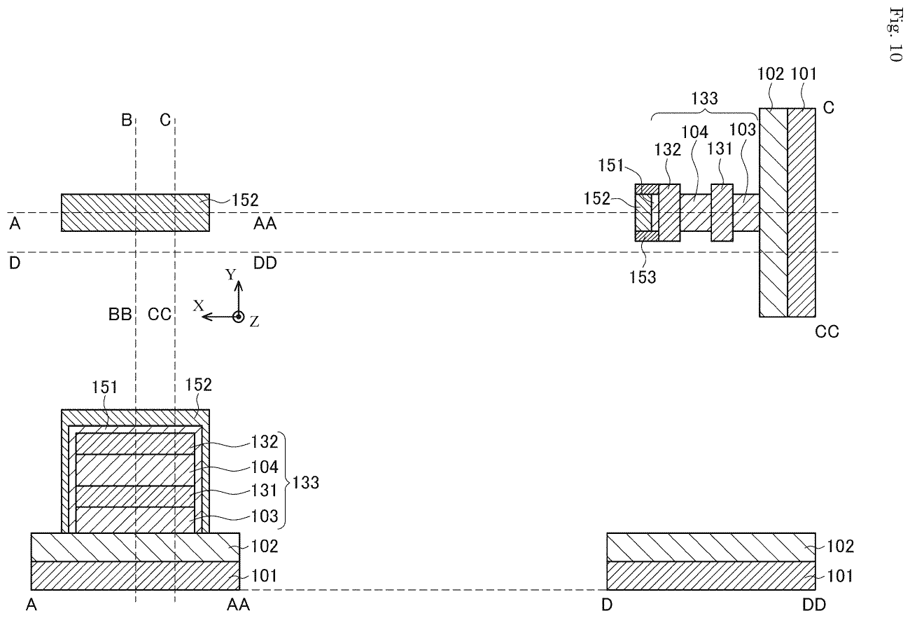

Subsequently, as shown in FIG. 9, the epitaxial layer 133 is etched using the dummy gate 152 and the dummy sidewall 153 as a mask. Specifically, all regions of the epitaxial layer 133 other than the region covered by the dummy gate 152 and the dummy sidewall 153 are removed.

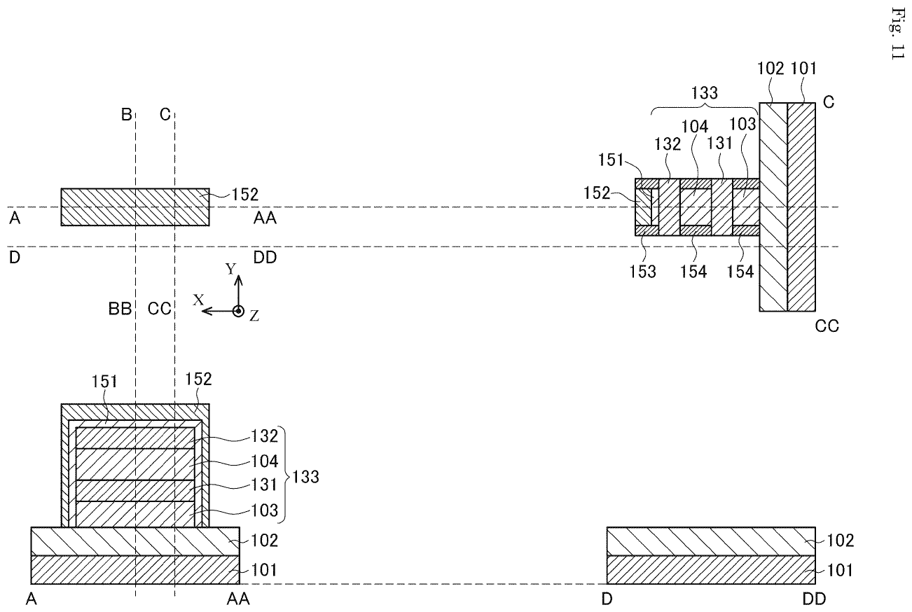

Next, as shown in FIG. 10, a part of the second SiGe layer 104 and the first SiGe layer 103 exposed to the side surface of the epitaxial layer 133 in the Y direction is side-etched by wet etching. The thickness in the Y direction of the first SiGe layer 103 and the second SiGe layer 104 to be side-etched may be, for example, approximately the same as the thickness of the dummy sidewall 153 in the Y direction.

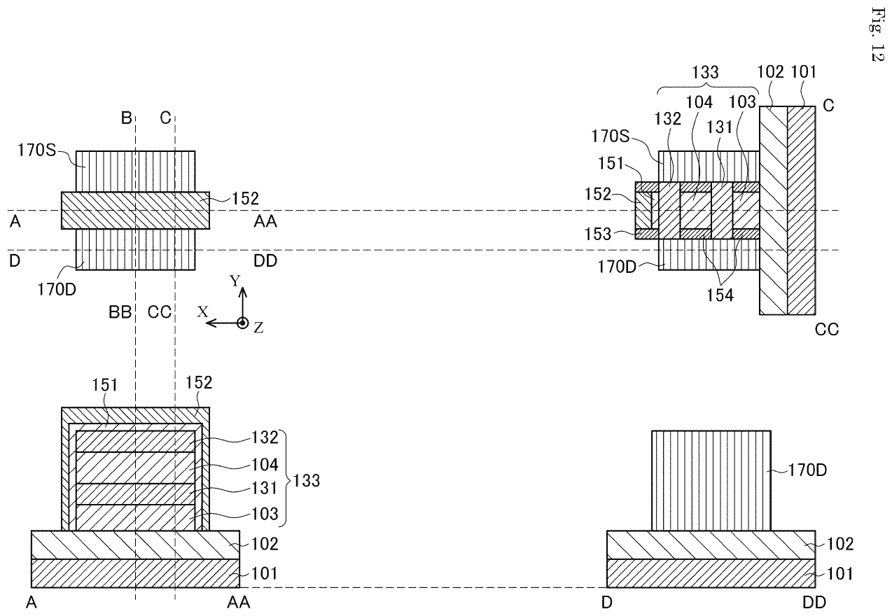

Thereafter, as shown in FIG. 11, SiN (not shown) is deposited in the side-etched openings, whereby the spacer layer 154 is formed. The spacer layer 154 protruding from the side surfaces of the epitaxial layer 133 in the Y direction is removed by anisotropic etching such as RIE (Reactive Ion Etching). In this way, the side surfaces of the epitaxial layer 133 in the Y direction are smoothed.

The spacer layer 154 is provided to insulate the source layer 170S and drain layer 170D from the gate electrode 150 with low capacitance. Further, the spacer layer 154 can support the first Si layer 131 and the second Si layer 132 in the Z direction, and can prevent the source layer 170S and the drain layer 170D from being etched during etching of the first SiGe layer 103 and the second SiGe layer 104, which will be described later.

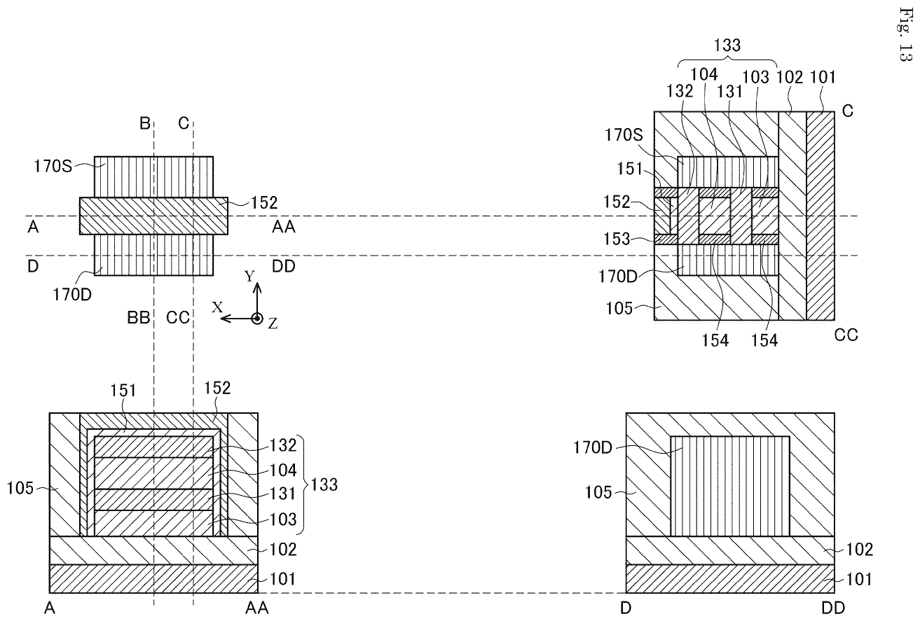

Next, as shown in FIG. 12, the source layer 170S and the drain layer 170D are formed to be in contact with both side surfaces of the epitaxial layer 133 in the Y direction. The source layer 170S and the drain layer 170D may be formed, for example, by causing Si to be epitaxially grown while introducing second conductivity type impurities from the first Si layer 131 and the second Si layer 132 that are not covered with the spacer layer 154.

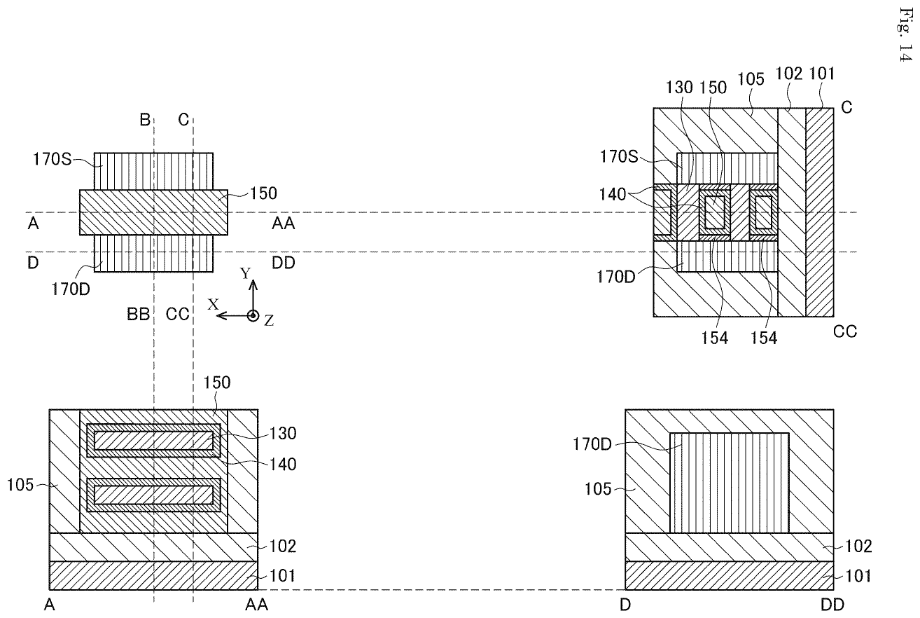

Subsequently, as shown in FIG. 13, an interlayer insulating layer 105 is deposited up to the upper surface of the dummy gate 152 in the Z direction. In this way, the interlayer insulating layer 105 can bury the epitaxial layer 133, the source layer 170S, and the drain layer 170D. The interlayer insulating layer 105 may be made of, for example, SiOₓ, SiN, or SiON.

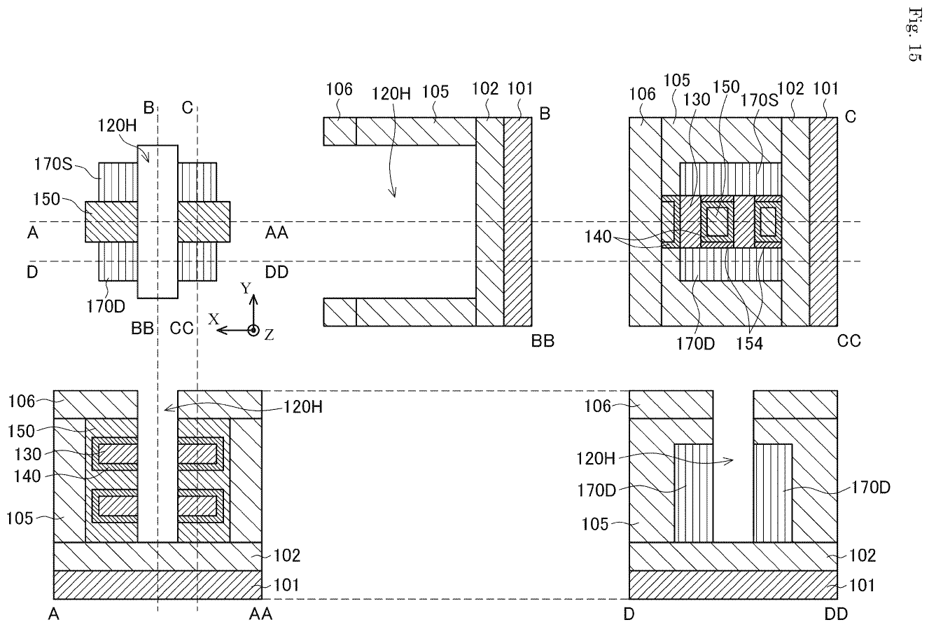

Next, as shown in FIG. 14, a channel layer 130, a gate insulating film 140, and a gate electrode 150 are formed.

Specifically, after the dummy gate 152, dummy sidewall 153, and dummy insulating film 151 are removed, the first SiGe layer 103 and the second SiGe layer 104 are removed by etching. As a result, the first Si layer 131 and the second Si layer 132 become a channel layer 130 having a nanowire or nanosheet structure in which both side surfaces of the Si layers in the Y direction are sandwiched between the source layer 170S and the drain layer 170D, and the surfaces in the Z direction are supported by the spacer layer 154.

After that, a gate insulating film 140 is formed on the surfaces of the channel layer 130 (the first Si layer 131 and the second Si layer 132), the spacer layer 154, and the substrate insulating layer 102 exposed by the removal of the first SiGe layer 103 and the second SiGe layer 104. In this way, the gate insulating film 140 can cover the exposed upper and lower surfaces of the channel layer 130 in the Z direction and both side surfaces in the X direction. The gate insulating film 140 may be made of, for example, a high dielectric constant material such as HfO₂.

Further, a gate electrode 150 is formed to fill the space created by the removal of the first SiGe layer 103 and the second SiGe layer 104. In this way, the gate electrode 150 can cover the gate insulating film 140 and fill the space between the interlayer insulating layers 105. The gate electrode 150 may be made of a conductive material such as TiN.

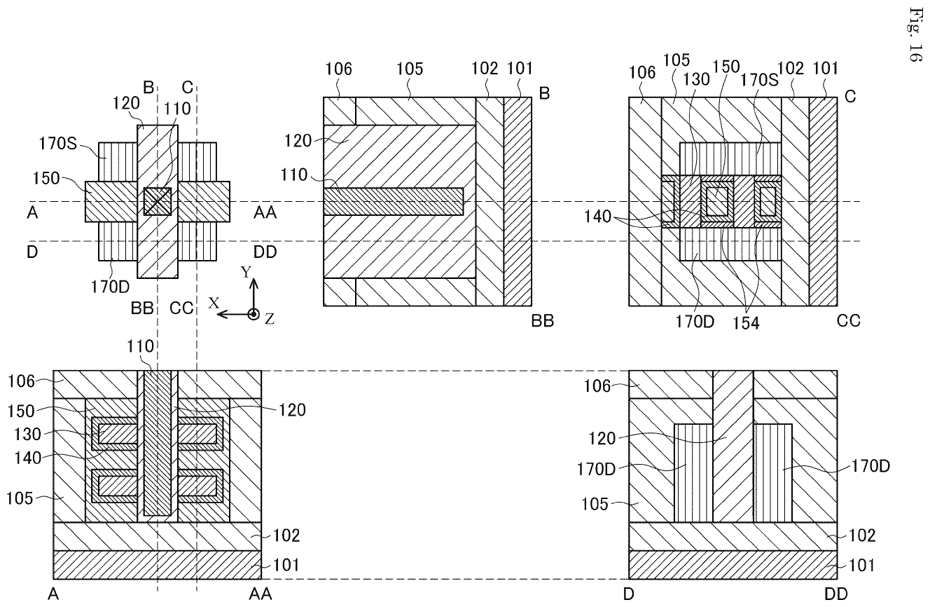

Subsequently, as shown in FIG. 15, after the interlayer insulating layer 106 is formed, an opening 120H extending in the Y direction is formed by etching to divide the channel layer 130 and the gate electrode 150 extending in the X direction. The opening 120H extending in the Y direction is provided, for example, to penetrate the interlayer insulating layers 105 and 106, the channel layer 130, the gate electrode 150, the source layer 170S, and the drain layer 170D so that the substrate insulating layer 102 is exposed.

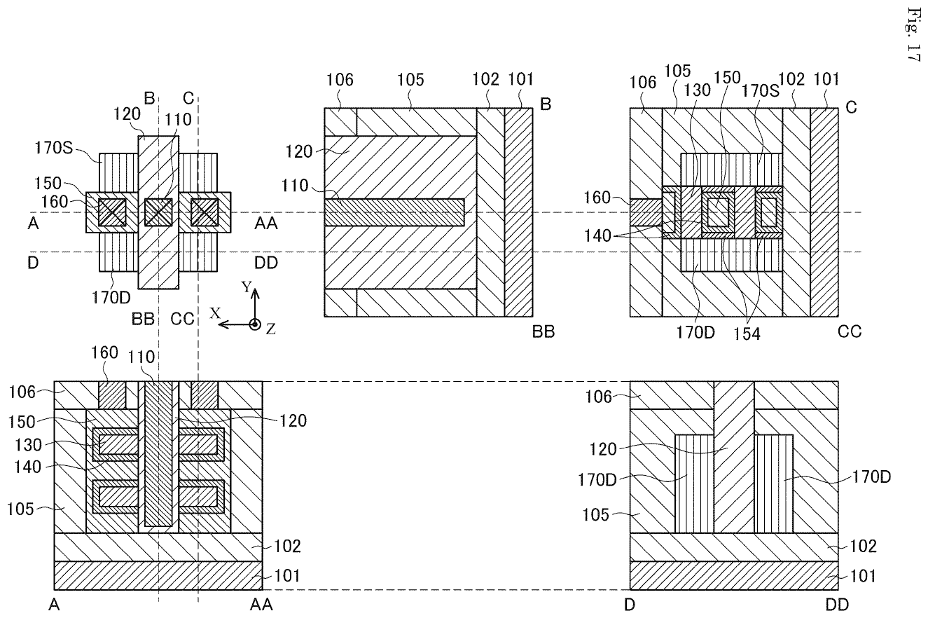

Next, as shown in FIG. 16, after a body insulating layer 120 is formed to fill the opening 120H, a body electrode 110 extending in the Z direction is formed at a position corresponding to the channel layer 130. Specifically, first, the body insulating layer 120 is formed by filling the opening 120H with an insulating material such as SiOₓ, SiN, or SiON. Next, an opening is formed in the body insulating layer 120 at a position corresponding to the position where the channel layer 130 is formed, and the body electrode 110 extending in the Z direction is formed to fill the opening. The body electrode 110 may be made of a conductive material such as TiN, for example. In this way, the body electrode 110 can supply a body potential to the channel layer 130 through capacitive coupling via the body insulating layer 120.

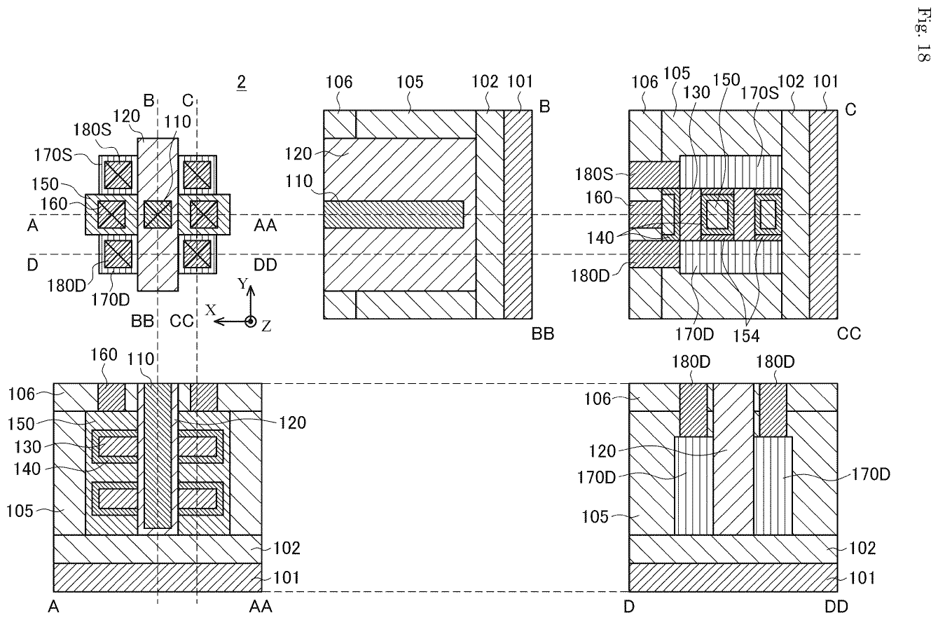

Subsequently, as shown in FIG. 17, a gate contact 160 is formed on the gate electrode 150. Specifically, an opening exposing the gate electrode 150 is formed at a position between the source layer 170S and the drain layer 170D of the interlayer insulating layer 106, and the opening is filled with a conductive material such as W, whereby the gate contact 160 is formed.

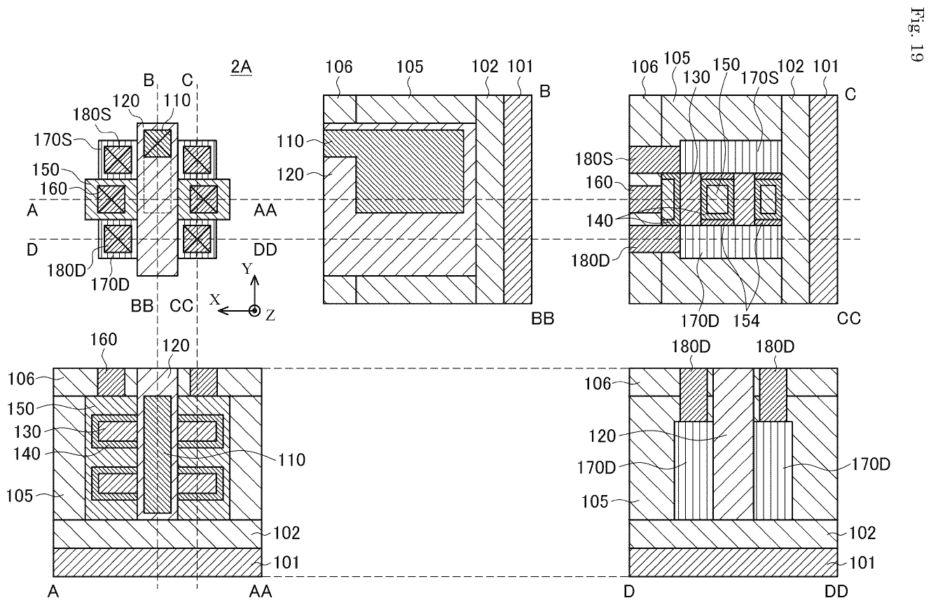

Thereafter, as shown in FIG. 18, a source electrode 180S is formed on the source layer 170S, and a drain electrode 180D is formed on the drain layer 170D. Specifically, openings that expose the source layer 170S and drain layer 170D are formed at positions sandwiching the gate contact 160 of the interlayer insulating layers 105 and 106, and the openings are filled with a conductive material such as W, whereby the source electrode 180S and the drain electrode 180D are formed.

Through the above-described steps, the semiconductor device 2 is formed. According to this configuration, the semiconductor device 2 can supply a body potential to each of the channel layers 130 provided on both sides of the body insulating layer 120 extending in the Y direction by the body electrode 110 provided inside of the body insulating layer 120 to extend in the Z direction. Therefore, the semiconductor device 2 can more easily supply the body potential to the channel layer 130 having a nanowire or nanosheet structure.

Note that the method for manufacturing the semiconductor device 1 according to the first structure is substantially the same as the method for manufacturing the semiconductor device 2 according to the second structure described above. Therefore, a description of the method for manufacturing the semiconductor device 1 according to the first structure will be omitted.

### 3. Modification Example

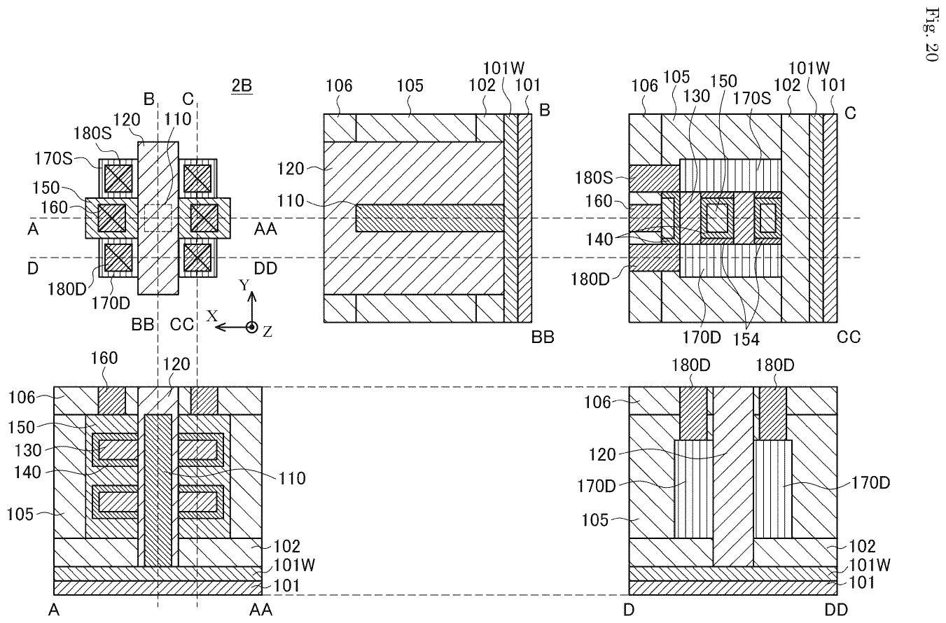

Next, first to fourth modification examples of the semiconductor device 2 will be described with reference to FIGS. 19 to 22. The first to fourth modification examples are modification examples regarding the structure for supplying the body potential to the body electrode 110.

### 3.1. First Modification Example

FIG. 19 is an explanatory diagram showing a planar configuration of a semiconductor device 2A according to a first modification example viewed from above, and a cross-sectional structure of the semiconductor device 2A along a predetermined cutting line.

As shown in FIG. 19, in the first modification example, the body electrode 110 is embedded inside of the body insulating layer 120 and is exposed to the surface of the body insulating layer 120 at a position different from the position where the channel layer 130 is provided. Specifically, the body electrode 110 is exposed to the surface of the body insulating layer 120 at a position further away in the Y direction from the position where the channel layer 130 is provided, and is capacitively coupled to the channel layer 130 by extending inside of the body insulating layer 120 in the Y direction.

According to the first modification example, in the semiconductor device 2A, the contact position for electrically connecting the body electrode 110 to external wiring or the like can be changed. Specifically, in the semiconductor device 2A, the contact position of the body electrode 110 can be shifted in the Y direction from the position facing the channel layer 130. Therefore, the semiconductor device 2A can further increase the flexibility of the wiring layout for the body electrode 110.

### 3.2. Second Modification Example

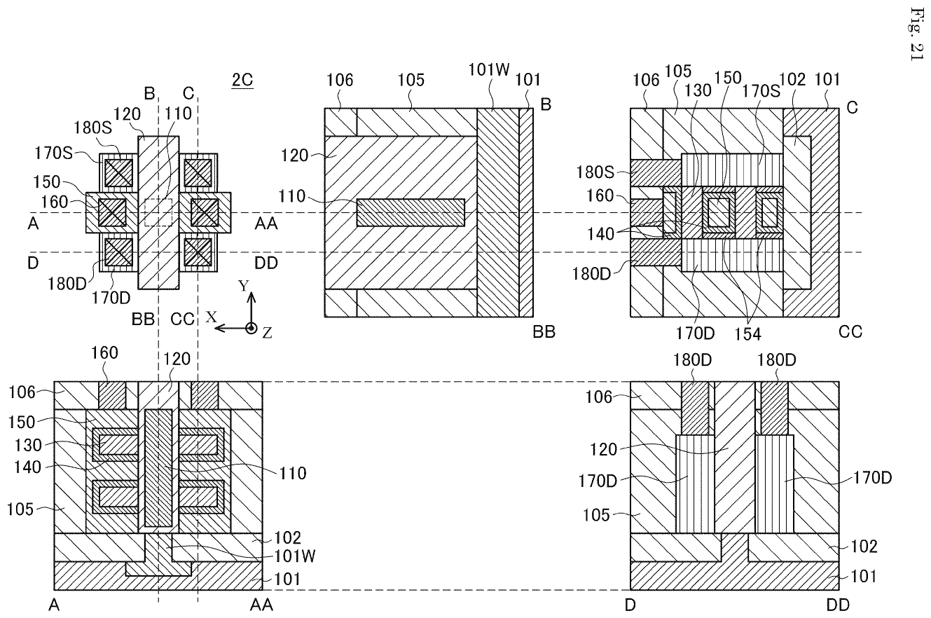

FIG. 20 is an explanatory diagram showing a planar configuration of a semiconductor device 2B according to a second modification example viewed from above, and a cross-sectional structure of the semiconductor device 2B along a predetermined cutting line.

As shown in FIG. 20, in the second modification example, the semiconductor layer 101 is provided with a well region 101W doped with a first conductivity-type impurity, and the body electrode 110 is supplied with a body potential via the well region 101W.

Specifically, the semiconductor layer 101 is provided with the well region 101W doped with a first conductivity type impurity across the plurality of semiconductor devices 2B. The body insulating layer 120 is provided to penetrate the substrate insulating layer 102 and be in contact with the well region 101W. The body electrode 110 is not exposed to the surface of the body insulating layer 120 and is provided to be electrically connected to the well region 101W by extending in the Z direction inside of the body insulating layer 120.

According to the second modification example, a body potential is supplied to the body electrode 110 via the well region 101W provided in the semiconductor layer 101. Therefore, the body electrode 110 can supply a body potential to the channel layer 130 via capacitive coupling by the body insulating layer 120.

Further, since the well region 101W is provided in the semiconductor layer 101 over the plurality of semiconductor devices 2B, the same body potential can be simultaneously supplied to the body electrodes 110 of the plurality of semiconductor devices 2B. According to the second modification example, since a back bias is simultaneously applied to the plurality of semiconductor devices 2B formed on the same substrate, it is possible to control the back bias of the plurality of semiconductor devices 2B with a simpler structure.

Note that the body electrode 110 shown in FIG. 20 may not be electrically connected to the well region 101W, but may be capacitively coupled via the body insulating layer 120. Even in such a case, the body electrode 110 can be supplied with the body potential from the well region 101W through capacitive coupling.

### 3.3. Third Modification Example

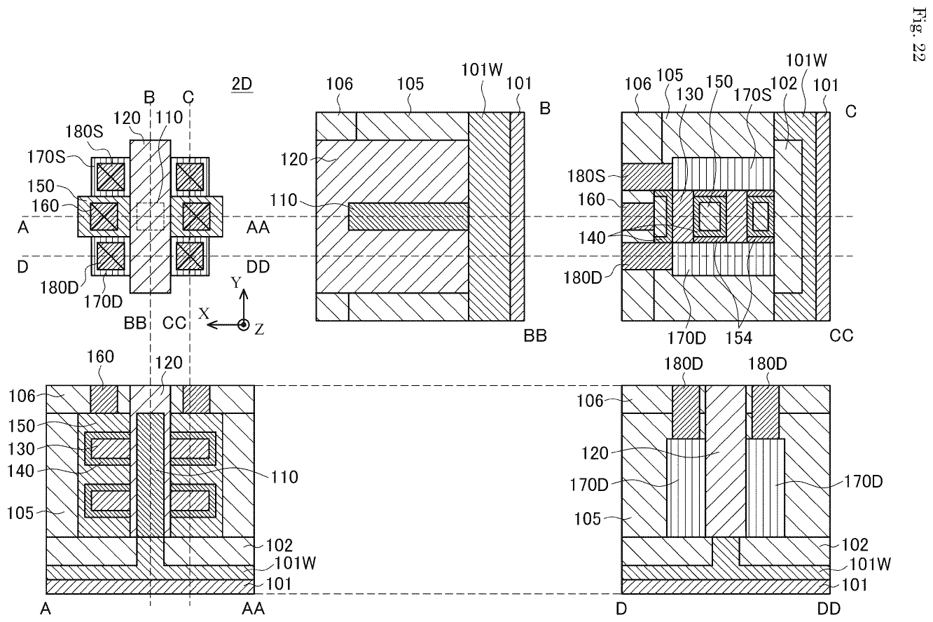

FIG. 21 is an explanatory diagram showing a planar configuration of a semiconductor device 2C according to a third modification example viewed from above, and a cross-sectional structure of the semiconductor device 2C along a predetermined cutting line.

As shown in FIG. 21, in the third modification example, the semiconductor device 2C is provided on a Si substrate including a semiconductor layer 101, and a substrate insulating layer 102 is provided on the semiconductor layer 101 in the region where a gate electrode 150, a source layer 170S, and a drain layer 170D are provided. The substrate insulating layer 102 is provided to electrically insulate the semiconductor layer 101 from the gate electrode 150, the source layer 170S, and the drain layer 170D. A well region 101W doped with a first conductivity type impurity is provided in the semiconductor layer 101, and a body potential is supplied to the body electrode 110 via the well region 101W.

Specifically, the semiconductor layer 101 is provided with the well region 101W doped with a first conductivity type impurity for each semiconductor device 2C, and the body insulating layer 120 is provided on the well region 101W provided in the semiconductor layer 101. The body electrode 110 is not exposed to the surface of the body insulating layer 120 and can be capacitively coupled to the well region 101W via the body insulating layer 120 by extending inside of the body insulating layer 120 in the Z direction.

According to the third modification example, a body potential is supplied to the body electrode 110 via the well region 101W provided in the semiconductor layer 101. Therefore, the body electrode 110 can supply a body potential to the channel layer 130 via capacitive coupling by the body insulating layer 120. Further, since the well region 101W is provided for each semiconductor device 2C, the semiconductor devices 2C can each independently supply a body potential to the channel layer 130.

### 3.4. Fourth Modification Example

FIG. 22 is an explanatory diagram showing a planar configuration of a semiconductor device 2D according to a fourth modification example viewed from above, and a cross-sectional structure of the semiconductor device 2D along a predetermined cutting line.

As shown in FIG. 22, in the fourth modification example, the semiconductor device 2D is provided on a Si substrate including a semiconductor layer 101, and a substrate insulating layer 102 is provided on the semiconductor layer 101 in a region where a gate electrode 150, a source layer 170S, and a drain layer 170D are provided. The substrate insulating layer 102 is provided to electrically insulate the semiconductor layer 101 from the gate electrode 150, the source layer 170S, and the drain layer 170D. A well region 101W doped with a first conductivity type impurity is provided in the semiconductor layer 101, and a body potential is supplied to the body electrode 110 via the well region 101W.

Specifically, the semiconductor layer 101 is provided with the well region 101W doped with a first conductivity type impurity across the plurality of semiconductor devices 2D, and the body insulating layer 120 is provided in the well region 101W provided in the semiconductor layer 101. The body electrode 110 is not exposed to the surface of the body insulating layer 120 and is provided to be electrically connected to the well region 101W by extending in the Z direction inside of the body insulating layer 120.

According to the fourth modification example, a body potential is supplied to the body electrode 110 via the electrically connected well region 101W. Therefore, the body electrode 110 can supply a body potential to the channel layer 130 via capacitive coupling by the body insulating layer 120.

Further, since the well region 101W is provided in the semiconductor layer 101 over the plurality of semiconductor devices 2D, the same body potential can be simultaneously supplied to the body electrodes 110 of the plurality of semiconductor devices 2D. According to the fourth modification example, a back bias is simultaneously applied to the plurality of semiconductor devices 2D formed on the same substrate. Thus, the back bias of the plurality of semiconductor devices 2D can be controlled with a simpler structure.

It should be noted that the method for manufacturing the semiconductor devices 2A to 2D according to the first to fourth modification examples can be easily conceived by a person skilled in the art by applying the method for manufacturing the semiconductor device 2 according to the second structure described above and a known semiconductor process. Therefore, a description of the manufacturing methods of the semiconductor devices 2A to 2D according to the first to fourth modification examples will be omitted.

Although the preferred embodiments of the present disclosure have been described in detail with reference to the accompanying figures as described above, the technical scope of the present disclosure is not limited to such examples. It is apparent that those having ordinary knowledge in the technical field of the present disclosure could conceive various modification examples or revisions within the scope of the technical ideas set forth in the claims, and it should be understood that these also naturally fall within the technical scope of the present disclosure.

Further, the effects described in the present specification are merely explanatory or exemplary and are not intended as limiting. That is, the techniques according to the present disclosure may exhibit other effects apparent to those skilled in the art from the description herein, in addition to or in place of the above-described effects.

Further, the following configurations also fall within the technical scope of the present disclosure.
(1)

A semiconductor device including:
a body electrode extending in a direction perpendicular to a main surface of a substrate;
a channel layer extending from a side surface of the body electrode in a first direction parallel to the main surface via an insulating film;
a source layer and a drain layer that are in contact with side surfaces of the channel layer in a second direction perpendicular to the first direction and sandwich the channel layer; and
a gate electrode provided between the source layer and the drain layer and covering the channel layer with a gate insulating film interposed therebetween.
(2)

The semiconductor device according to (1), wherein
the substrate includes a semiconductor layer and a substrate insulating layer provided on the semiconductor layer.
(3)

The semiconductor device according to (1) or (2), wherein
a potential of the body electrode is controlled from a side opposite to a side where the substrate is provided.
(4)

The semiconductor device according to (2), wherein
a potential of the body electrode is controlled via a well provided in the semiconductor layer.
(5)

The semiconductor device according to (4), wherein
the body electrode is electrically connected to the well.
(6)

The semiconductor device according to (4), wherein
the body electrode is capacitively coupled to the well via the insulating film.
(7)
the substrate insulating layer is partially provided on the semiconductor layer, and
the gate electrode is provided on the substrate insulating layer.
(8)

The semiconductor device according to any one of (1) to (7), wherein
the channel layer is in contact with the gate electrode via the gate insulating film on three surfaces: side surfaces in the first direction, and upper and lower surfaces in the direction perpendicular to the main surface.
(9)

The semiconductor device according to (8), wherein
a plurality of the channel layers are provided to be spaced apart from each other in the direction perpendicular to the main surface.
(10)

The semiconductor device according to (9), wherein
the source layer and the drain layer are provided extending in the direction perpendicular to the main surface and are electrically connected to side surfaces of the plurality of the channel layers.
(11)

The semiconductor device according to any one of (1) to (10), wherein
the channel layer is provided extending in the first direction on both sides of the body electrode.
(12)

The semiconductor device according to (11), wherein
the channel layers provided on both sides of the body electrode have the same conductivity type.
(13)

The semiconductor device according to (11) or (12), wherein
the semiconductor device is provided line-symmetrically with respect to a straight line extending in the second direction through the body electrode.
(14)

The semiconductor device according to any one of (1) to (13), wherein
the channel layer has a nanowire structure or a nanosheet structure.

### Reference Signs List

1, 2, 2A, 2B, 2C, 2D Semiconductor device
101 Semiconductor layer
102 Substrate insulating layer
105, 106 Interlayer insulating layer
11, 110 Body electrode
12, 120 Body insulating layer
13, 130 Channel layer
14, 140 Gate insulating film
15, 150 Gate electrode
16, 160 Gate contact
17D, 170D Drain layer
17S, 170S Source layer
18D, 180D Drain electrode
18S, 180S Source electrode
19 Capacitance control layer
101W Well region
103 First SiGe layer
104 Second SiGe layer
131 First Si layer
132 Second Si layer
133 Epitaxial layer
151 Dummy insulating film
152 Dummy gate
153 Dummy sidewall
154 Spacer layer

1. A semiconductor device comprising:
a body electrode extending in a direction perpendicular to a main surface of a substrate;
a channel layer extending from a side surface of the body electrode in a first direction parallel to the main surface via an insulating film;
a source layer and a drain layer that are in contact with side surfaces of the channel layer in a second direction perpendicular to the first direction and sandwich the channel layer; and
a gate electrode provided between the source layer and the drain layer and covering the channel layer with a gate insulating film interposed therebetween.

2. The semiconductor device according to claim 1, wherein
the substrate includes a semiconductor layer and a substrate insulating layer provided on the semiconductor layer.

3. The semiconductor device according to claim 1, wherein
a potential of the body electrode is controlled from a side opposite to a side where the substrate is provided.

4. The semiconductor device according to claim 2, wherein
a potential of the body electrode is controlled via a well provided in the semiconductor layer.

5. The semiconductor device according to claim 4, wherein
the body electrode is electrically connected to the well.

6. The semiconductor device according to claim 4, wherein
the body electrode is capacitively coupled to the well via the insulating film.

7. The semiconductor device according to claim 2, wherein
the substrate insulating layer is partially provided on the semiconductor layer, and
the gate electrode is provided on the substrate insulating layer.

8. The semiconductor device according to claim 1, wherein
the channel layer is in contact with the gate electrode via the gate insulating film on three surfaces: side surfaces in the first direction, and upper and lower surfaces in the direction perpendicular to the main surface.

9. The semiconductor device according to claim 8, wherein
a plurality of the channel layers are provided to be spaced apart from each other in the direction perpendicular to the main surface.

10. The semiconductor device according to claim 9, wherein
the source layer and the drain layer are provided extending in the direction perpendicular to the main surface and are electrically connected to side surfaces of the plurality of the channel layers.

11. The semiconductor device according to claim 1, wherein
the channel layer is provided extending in the first direction on both sides of the body electrode.

12. The semiconductor device according to claim 11, wherein
the channel layers provided on both sides of the body electrode have the same conductivity type.

13. The semiconductor device according to claim 11, wherein
the semiconductor device is provided line-symmetrically with respect to a straight line extending in the second direction through the body electrode.

14. The semiconductor device according to claim 1, wherein
the channel layer has a nanowire structure or a nanosheet structure.
